(19) United States
(12) Patent Application Publication
(10) Pub. No.: US 2012/0256166 A1
(43) Pub. Date: Oct. 11, 2012

(54) DEPOSITION OF NANOPARTICLES

(75) Inventors: Lichun Chen, Southampton (GB); Michael Coelle, Schwanstetten (DE); Mark John Goulding, Ringwood (GB)

(73) Assignee: MERCK PATENT GESELLSCHAFT MIT BESCHRANKTER HAFTUNG, Darmstadt (DE)

(21) Appl. No.: 13/516,402

(22) PCT Filed: Nov. 16, 2010
(86) PCT No.: PCT/EP2010/006960

§ 371 Date: Jun. 15, 2012

(30) Foreign Application Priority Data
Dec. 17, 2009 (EP) 09015594.6

(51) Int. Cl. H01L 21/208; H01L 29/78; H01L 29/66; H01L 21/66; B82Y 40/00; B82Y 15/00

(52) U.S. Cl. 257/20; 438/502; 438/492; 257/15; 438/16; 438/17; 977/892; 977/938; 257/E21.114; 257/E21.53; 257/E21.531; 257/E29.255; 257/E29.168

(57) ABSTRACT

The invention relates to a process for deposition of elongated nanoparticles from a liquid carrier onto a substrate, and to electronic devices prepared by this process.

### FIELD OF THE INVENTION

The invention relates to a process for deposition of elongated nanoparticles from a liquid carrier onto a substrate, and to electronic devices prepared by this process.

### BACKGROUND AND PRIOR ART

Transistors based on single nanowires have very high mobility and high on-off ratio [Xiang et al., Nature, 441 (2006), 489-493]. The assembly of conducting or semiconducting nanoparticles, like nanowires (“NWs”) or nanotubes, into nanoscale devices and circuits can enable diverse applications in nanoelectronics and photonics. Individual semiconducting nanowires have already been configured as field-effect transistors (FETs) [Xiang et al., Nature, 441 (2006), 489-493], memory devices [Lee et al., Nature Nanotechnology, 2 (2007), 626-630], photodetectors and solar cells [Tian et al., Nature, 449 (2007), 885-889; Hayden et al., Nature Materials, 5 (2006), 352-356].

The prior art describes also methods to assemble nanowire devices based on a bottom-up method, i.e. nanowires are grown on a substrate and retained there. However, such methods are time consuming and too expensive for use in mass production processes and are difficult to control. Since meanwhile also methods for mass production of nanowires have been reported [Wan et al., Applied Physics Letters, 84(1) (2004),124-126], there is a need for techniques to deposit the nanowires prepared by such methods onto the substrate of their final destination (top-down method). The advantage of latter method is that it is significantly cheaper.

Some nanowire deposition methods have been developed, such as electric and magnetic induced alignment, flow alignment and blade coating All these alignment processes involve solvents in which the nanowires are dispersed. No matter whether the nanowires are aligned or not, during the drying process nanowires tend to aggregate together and the distribution and alignment efforts distort or vanish totally. The nanowires are relative stiff, which make the adhesion of nanowires to substrate very weak. After the nanowires are deposited from solution onto the substrate, the solution evaporates increasing the concentration. Furthermore, the nanowires move with the solvent resulting in the so called “coffee stain” effect. This is observed on two different scales: On a larger scale (mm to cm)—like accumulation at the edge of a droplet—and on a small scale. On the small scale long nanowires clump together with many short nanowires and nanoparticles generating spots.

The aggregated nanowires are disadvantageous for nanowire transistors. For example, the lower wires in the clumps prevent nanowires to attach to the dielectric layer. Moreover they screen the electric field. Thus, the electric field introduced by the gate electrode has less effect and thus gives strongly reduced device performance. In effect, clump formation may cause a big drop of the on/off ratio of the transistor. The nanowires transistors with clumps usually have an on/off ratio around 10 or less.

To remove clumps is very important. One task of the invention was to find a method for depositing nanowires without clumps on a surface of a substrate.

In prior art methods are described using liquid flow (US 20030186522) and soft print (WO 2005/017962) to align and deposit nanowires or nanoparticles on substrates, which are different from the approach described herein.

Furthermore, the used nanowires may also contain some short nanowires and nanoparticles. These smaller particles move faster than the longer nanowires and easily form aggregates. Such aggregation remarkably reduces the performance of nanowires transistors.

Thus, there is still a need for an improved, simple and effective process for the deposition of elongated nanoparticles which can be used in the fabrication of electronic devices like transistors, but also other nanoparticle-based electronics such as diodes (LEDs, photodiodes), sensors and solar cells, especially for mass production of such devices, and which does not have the drawbacks of the methods disclosed in prior art as explained above. One aim of the present invention is to provide such an improved deposition process. Another aim of the invention is to provide improved electronic devices, especially transistors and solar cells, obtained by such a process. Other aims of the present invention are immediately evident to the person skilled in the art from the following detailed description.

It was found that these aims can be achieved by providing a process as claimed in the present invention.

Herein, we demonstrate a simple deposition technique for elongated nanoparticles, where nanoparticles are immobilized on a substrate right after deposition. The later dry process does not change their position anymore. This method is very useful to produce randomly distributed nanoparticles on substrates without aggregation or clumps. The method is also useful for drying a thin film of aligned nanoparticles without disturbing the alignment by rolling away most of the superfluous solvent. The method shall be referred to as the “roll cast method”.

The invention relates to a process for deposition of elongated nanoparticles onto a substrate, comprising the steps:

wetting the substrate with a liquid carrier comprising elongated nanoparticles, and rolling of a cylindrical roller over the substrate wetted by the said liquid carrier.

Preferably the deposited nanoparticles and the residual liquid carrier are dried in a third step. Usually the volatile parts of the liquid carrier are evaporated. Alternatively or additionally drying includes that any liquid monomers are polymerized. The effect of drying is that the deposited nanoparticles are further immobilized on the substrate.

The roll cast method in fact is an ideal method to avoid the clumps formation on the substrate. In the roll cast process, the roller squeezes the nanowire dispersion shortly after deposition, leading to a very thin liquid layer that is not able to lift the nanowire or relocate them. The wires are immobilized in an ideal and random configuration.

FIG. 1 shows the transfer curves of a nanowire transistor (20 μm source and drain channel) deposited from a solution by using the roll cast method. The on/off ratio of 6*10⁴ is very high. Here it is demonstrated that the roll cast method is an ideal method to deposit nanowires without causing clumps of shorter nanowires and nanoparticles in the dispersion.

The roll cast method can be regarded as a method which can randomly distribute nanoparticles on a substrate without causing aggregation of the nanoparticles in discrete locations on the surface.

This method is different from gravure printing where the material is supposed to transfer from a roller to substrate or otherwise; it is in a way similar to bar coating and blade coating. However, in those cases, the gap between the bar (bar coating) or the blade (blade coating) and the substrate is fixed. In the roll cast, the roller softly touches the elongated nanoparticles on the substrate without or with little damage during operation. The distance between the roller and the substrate is determined by the thickness of the nanoparticle film, which ensures that the residual solution thickness is limited by the nanoparticle thickness. The light weight roller also limits the damage to the nanoparticles.

This method and its principle can be used in combination with alignment techniques to complete a nanowire alignment and deposition process. The invention demonstrates a method for depositing nanowire films that are free from accumulations of nanowires, hereafter named “clumps”. By using this method evenly and randomly distributed NWs can be deposited on substrates. This method is very fast and reproducible.

Accordingly the process according to the invention is ideal for the quick characterization of elongated nanoparticles and for mass production. It shows a strong improvement in reproducible device fabrication and is therefore an ideal candidate for device fabrication and material evaluation. A nanowire transistor with a high on/off ratio of 6*10⁴ has been fabricated using this method.

Preferably the roll cast method is performed with a roller of cylindrical shape, where the moving part may preferable rotate along its long cylindrical axis. The material of the roller is preferably chemically inert, so as to prevent interaction of the roller with the nanoparticles or the solvent. The surface of the roller is preferably coated or treated chemically in order to minimize adhesion of the nanoparticles to it. With conventional nanoparticles the best results are usually obtained if the surface of the roller is made hydrophobic.

Preferably the roller is covered with a soft polymer in order to ensure continuous contact between the roller and the substrate at constant, small pressure. Most preferably the soft cover of the roller is effected by a hydrophobic polymer. The polymer coat has two functions: Firstly, it has a soft surface, which causes less damage to nanowires when rolling over them; secondly its hydrophobic surface avoids attaching the nanowires to it during the roll cast process. The soft polymer is preferably of a kind that repels the used nanoparticles, e.g. fluorinated polymers.

Preferably the nanoparticles are placed in contact with one or more device structures, preferably at least one of the working electrodes (source/drain, gate electrode).

It is advantageous for the deposition of the nanoparticles if they have an pronounced elongated shape, like nanowires, nanotubes, nanorods, nanoribbons, nanowhiskers, or even platelet shape like nanodiscs. In a preferred aspect of the current invention, the process is performed with elongated nanoparticles which are nanowires, especially with semiconducting nanowires.

The invention further relates to the use of nanoparticles deposited by a process according to the present invention as charge transport, conducting or semiconducting component in an electronic, electro-optical, photo-voltaic, electroluminescent or optical device.

The invention further relates to a process for preparing an electronic, electro-optical, photo-voltaic, electroluminescent or optical device, preferably an electronic device, comprising the steps of
a) applying working electrodes, preferably source and drain electrodes, onto a substrate or onto a dielectric layer,
b) depositing a layer of elongated and preferably semiconducting nanoparticles, dispersed in a fluid, onto the substrate or dielectric layer and the working electrodes,
c) rolling a cylindrical roller over the substrate or dielectric layer while the substrate or dielectric layer is wetted by said fluid with the nanoparticles and removing the fluid from the nanoparticle layer or polymerizing any monomer, and
d) optionally providing one or more further functional layers onto the nanoparticle layer,

wherein it is also possible to carry out the steps in a different order.

Preferably the steps are carried out in the given order.

The invention further relates to a device comprising nanoparticles deposited by a process as described above and below.

The invention further relates to a semiconducting layer comprising elongated nanoparticles and prepared by a process according to the invention.

The invention further relates to an electronic, electro-optical, photo-voltaic, electroluminescent or optical device comprising the deposited nanowires and working electrodes, wherein the nanoparticles connect the working electrodes. The working electrodes are preferably located on a substrate, more preferably on a flat substrate.

The device according to the invention preferably comprises a plurality of nanoparticles. The process according to the invention is especially useful for depositing a plurality of nanoparticles, in contrast to other methods, which are preferably useful for placing just a single or a limited number of nanoparticles to dedicated locations.

The device comprises preferably a field-effect transistor FET comprising:
a substrate,
a gate electrode,
a dielectric layer,
source and drain electrodes, and
a semiconducting layer comprising nanoparticles deposited by a process as described above and below.

Usually the semiconducting layer connects the source and drain electrodes.

The electronic, electrooptical, photo-voltaic electroluminescent or optical devices include, without limitation, (organic) field effect transistors ((O)FET), integrated circuits (IC), (organic) thin film transistors ((O)TFT), radio-frequency identification tags (RFID), (organic) light emitting diodes ((O)LED), (organic) light emitting transistors ((O)LET), electroluminescent displays, (organic) photovoltaic ((O)PV) cells, (organic) solar cells ((O-)SC), flexible (O)PVs and (O-)SCs, (organic) laser diodes ((O)-laser), (organic) integrated circuits ((O-)IC), lighting devices, sensor devices, electrode materials, photoconductors, photodetectors, electrophotographic recording devices, capacitors, charge injection layers, Schottky diodes, planarising layers, antistatic films, conducting substrates, conducting patterns, photoconductors, electrophotographic devices, organic memory devices, biosensors, biochips, optical polarizers, optical retarders, and optical compensators.

Definitions of Terms

The term “nanoparticles” (also referred to in the literature as “nanomaterials”) includes, but is not limited to nanowires, nanorods, nanowhiskers, nanotubes, nanodiscs, nanotetrapods, nanoribbons and/or combinations thereof, as defined for example in U.S. Pat. No. 7,344,961, the entire disclosure of which is incorporated into this application by reference.

The term “elongated” specifically stands for particles that have an aspect ratio of their longest diameter and their smallest diameter of 5 or more, preferably of 10 or more, more preferably of 20 or more and most preferably of 100 or more.

The terms “group II”, “group IV”, etc. refer to the periodic table of elements.

The term “nanowires” or “NWs” means any elongated, preferably conducting or semiconducting, particle or material that includes at least one cross sectional dimension <500 nm, preferably <100 nm, and has an aspect ratio (length:width) of >10, preferably >50, more preferably >100. Nanowires can have a variable diameter or can have a substantial uniform diameter. Typically the diameter is evaluated away from the ends of the nanowire (e.g. over the central 20%, 50% or 80% of the nanowire). A nanowire can be straight or can be curved or bent, over the entire length of its long axis or a portion thereof. For this invention straight nanowires are preferred over bent ones, which are again preferred over coiled ones. Nanowires according to this invention can expressly exclude carbon nanotubes, and, in certain embodiments, exclude elongated particles having a smallest diameter greater than 150 nm.

The term “working electrode” refers to the electrode(s) of any device that are located vicinal to or directly at the place of deposition of the nanoparticles. In some preferred embodiments the working electrodes are the source electrode and/or the drain electrode, e.g. of a transistor-like device.

The nanoparticles used in the present invention preferably have an anisotropic shape, i.e. they have different length and width/diameter, like for example nanowires or nanotubes. The diameter or width of the nanowires is typically in the range from a few namometers to several hundreds of nanometers, preferably from 5 to 100 nm. The length of the nanoparticles is typically over 500 nm, preferably from 1 to 100 micrometer (μm). The aspect ratio (length:width) is preferably from 5 to 1000. This anisotropic shape makes the nanoparticles more adapted to deposit on the substrate by the inventive method and adds interesting functionality to the deposition layer. Nanowires and nanotubes are especially preferred. Especially preferred are semiconducting nanowires.

The nanoparticles used preferably for this invention can be substantially homogeneous in material properties, or in some embodiments can also be heterogeneous (like for example nanowire heterostructures). They can be fabricated from essentially any convenient material or materials, and can be for example substantially crystalline, substantially monocrystalline, polycrystalline, amorphous or a combination thereof.

Preferably nanoparticles are used for the invention which are readily dispersed in the fluid.

Generally a broad variety of materials can be used as nanoparticles, including, without limitation, semiconducting materials selected from the group consisting of Group IV semiconductors, Group III-V semiconductors, Group II-VI semiconductors, transition metals, or alloys or mixtures of the aforementioned. Especially preferred Group IV semiconductors are Si, Ge, Sn, and alloys thereof. Further preferred are alloys of Group III-V semiconductors with other Group III and/or Group V elements, and alloys of Group II-VI semiconductors with other Group II and/or Group VI elements. These classes of nanomaterials work very well with the inventive process.

Suitable and preferred semiconducting materials include, without limitation, Si, Ge, Sn, Se, Te, B, C (including diamond), P, B—C, B—P(BP₆), B—Si, Si—C, Si—Ge, Si—Sn and Ge—Sn, SiC, BN, BP, BAs, AlN, AlP, AlAs, AlSb, GaN, GaP, GaAs, GaSb, InN, InP, InAs, InSb, ZnO, ZnS, ZnSe, ZnTe, CdS, CdSe, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, Cul, AgF, AgCl, AgBr, Agl, BeSiN₂, CaCN₂, ZnGeP₂, CdSnAs₂, ZnSnSb₂, CuGeP₃, CuSi₂P₃, (Cu, Ag)(Al, Ga, In, Ti, Fe)(S, Se, Te)₂, Si₃N₄, Ge₃N₄, Al₂O₃, (Al, Ga, In)₂ (S, Se, Te)₃, Al₂CO, and any appropriate combination of two or more of the aforementioned materials.

The nanoparticles can also consist of or comprise other materials, including, without limitation, metals such as Au, Ag, Ni, Pd, Ir, Co, Cr, Al, Ti, Fe, Sn and the like, metal alloys, polymers including (semi-)conducting polymers, ceramics, and/or combinations thereof. Other conducting or semiconducting materials can also employed.

The nanoparticles can also be doped into p-type or n-type semiconductors. For example, they can contain a dopant selected from the group consisting of: a p-type dopant selected from Group III elements, in particular B, Al or In, an n-type dopant selected from Group V elements, in particular P, As and Sb, a p-type dopant selected from Group II elements, in particular Mg, Zn, Cd and Hg, a p-type dopant selected from Group IV elements, in particular C and Si, or an n-type dopant selected from the group consisting of Si, Ge, Sn, S, Se and Te. Other known dopant materials can also be employed.

The nanoparticles can essentially consist of one material, but can also have for example a core/shell structure, wherein the core and the shell surrounding it consist of or comprise different materials or different material compositions. For example, core/shell nanoparticles may consist of a nanoparticle core and a nanoparticle shell that comprise for example Group IV elements independently selected from the group consisting of C, Si, Ge and Sn. The shell can also consist of or comprise an insulating material, for example an oxide of a Group IV element.

An organic mono-layer is often deposited on the nanoparticles/nanowires.

This layer may play several roles:
Nanoparticles are better dispersible in solvent.
Protection of nanoparticles against oxidation.
Modification of the nanoparticle's workfunction.
Nanoparticles work well with the inventive process.

The organic mono layer can be of many types according to above functions, for example, alkyl, alkanethiol type etc. as described in J. Am. Chem. Soc (2004), 126(47),15466.

The nanowires or nanoribbons can also include carbon nanotubes, or nanotubes formed from conducting or semiconducting organic materials like for example pentacene, organic polymers, or transition metal oxides.

Nanoparticles can be produced by a variety of different methods. For example, nanowires can be grown by using a vapor-liquid-solid (VLS) technique. Solution based, surfactant mediated crystal growth has been described for producing spherical inorganic nanoparticles, like for example quantum dots, as well as elongated nanoparticles, like for example nanorods and nanotetrapods. Other methods have also been employed to produce nanoparticles, including vapour phase methods. For example, silicon nanocrystals have been reported produced by laser pyrolysis of silane gas.

A suitable method for preparing nanowires uses solution growth from a suitable precursor material, like metal halides or organometallic compounds of the above-mentioned elements. This can be achieved for example by exposing a nanowire precursor to a metal nanocrystal in a nanowire growth solution comprising an organic solvent at a suitable temperature. At elevated temperatures the precursor decomposes and forms the desired nanomaterial. The metal nanocrystals serve as seed particles that catalyze the elongated growth of the semiconductor nanowires. Suitable metal nanocrystals like gold colloids are known from prior art.

Suitable materials and shapes for nanoparticles and methods of their preparation are generally known to the skilled person and disclosed in the literature, for example in the documents cited above, or in US 2005/0029678 A1, A. T. Heitsch, D. D. Fanfair, H.-Y. Tuan & B. A. Korgel, J. Am. Chem. Soc. (2008), 130, 5346-7, T. Hanrath, B. A. Korgel, J. Am. Chem. Soc. 126 (2004), 15466-72, D. Fanfair et al. Crystal Growth & Design 5 (2005), 1971-6, A. M. Morales et al. Science (1998), 279, 208-11, WO 02/17362, WO 01/03208, and in U.S. Pat. No. 7,344,961 B2 and the references cited therein. The entire disclosure of the aforementioned documents concerning production of nanowires is incorporated into this application by way of reference.

In order to be applied by the liquid deposition technique, the nanoparticles should first be dispersed in a suitable fluid or solvent. The nanoparticles should be well dispersed. The fluidic medium can be a solvent or a solvent mixture, preferably of the organic solvent type. The preferred solvents usually depend on the nature of the surface of the NWs. For non passivated NWs, if the surface is oxidized, alcohol type of solvents are often used. For the surface-passivated NWs, there are many organic solvents that can be used.

Preferred fluids and solvents depend on the type of monolayer used for encapsulating the nanoparticles. For most alkyl or alkene type of monolayers medium polar halogenated solvents like chloroform and dichlorobenzene are good solvents. Preferred fluids generally comprise chlorobenzene, 1,2-dichlorobenzene, butanone or anisole. Solvents with a high dipolar moment are preferred, especially those having a permanent dipole moment of 1,5 D (Debye) or higher.

The solvent can additionally comprise one or more further components like, for example, surface-active compounds, lubricating agents, wetting agents, dispersing agents, hydrophobing agents, adhesive agents, flow improvers, defoaming agents, de-aerators, diluents which may be reactive or non-reactive, auxiliaries, colorants, dyes or pigments, sensitizers, stabilizers, other nanoparticles, or inhibitors.

Preferably the nanoparticles are passivated. The passivation layer may comprise, preferably it consists of alkenes, isoprene, or thiols, which are attached covalently or physically. Preferably the passivation agents are attached covalently to the nanoparticle surface by conversion into alkyl groups or a thio-ether, respectively.

After deposition of the nanoparticles, the solvent is usually removed, for example by letting it evaporate at ambient temperature and pressure. It is also possible to apply heat and/or reduced pressure to accelerate evaporation.

The layer of deposited nanoparticles can then be covered by another functional layer of the device or by one or more protective layers, for example deposited polymer dielectric layer on top for top gate transistors, or a polymer protection layer to avoid the oxygen damage of the nanoparticles.

The nanoparticles deposited by the process according to the present invention are useful as charge transport, semiconducting, electrically conducting, photoconducting or light-emitting materials in electronic, electrooptical, electroluminescent, photo-voltaic photoluminescent or optical components or devices.

Preferred devices are FETs, TFTs, ICs, logic circuits, capacitors, RFID tags, LEDs, LETs, PVs, solar cells, laser diodes, photoconductors, photodetectors, electrophotographic devices, electrophotographic recording devices, organic memory devices, sensor devices, charge injection layers, Schottky diodes, planarising layers, antistatic films, conducting substrates and conducting patterns. In these devices, the aligned nanoparticles of the present invention are typically applied as thin layers or films. Especially preferred are FETS and TFTs.

A preferred electronic device comprises the following components:
optionally a substrate,
one or more conductors, preferably electrodes,
an insulator layer comprising a dielectric,
a preferably semiconducting layer comprising nanoparticles deposited according to the invention.

A first preferred embodiment of the invention relates to a bottom gate (BG) FET device, comprising the following components in the sequence described below:
optionally a substrate,
a gate electrode,
an insulator layer comprising a dielectric,
source and drain electrodes, and
a semiconducting layer comprising nanoparticles deposited according to the invention.

The process for preparing this BG transistor device preferably comprises the steps of
applying a gate electrode on a substrate,
applying a dielectric layer on top of the gate electrode and the substrate,
applying source and drain electrodes on top of the dielectric layer,
depositing a layer of semiconducting nanoparticles, dispersed in a liquid carrier onto the dielectric layer and the source and drain electrodes,
rolling a cylindrical roller over the dielectric layer while the dielectric layer is wetted by the said liquid carrier and
removing the fluid from the nanoparticle layer,
optionally providing one or more further functional layers onto the nanoparticle layer.

A second preferred embodiment relates to a top gate (TG) FET device, comprising the following components in the sequence described below:
a substrate,
source and drain electrodes,
a semiconducting layer comprising roll casted nanoparticles,
an insulator layer comprising a dielectric, and
a gate electrode.

The process for preparing this TG transistor device preferably comprises the steps of
applying source and drain electrodes on a substrate,
depositing a layer of semiconducting nanoparticles, dispersed in a liquid carrier onto the substrate and the source and drain electrodes,
rolling a cylindrical roller over the substrate while the substrate is wetted by the said liquid carrier and
removing the fluid from the nanoparticle layer,
applying a dielectric layer on top of the nanoparticle layer, and
applying a gate electrode on top of the dielectric layer.

Variations of these device structures and processes can easily be performed by the person skilled in the art using conventional methods and materials known in the art, for example to provide top contact (TG) or bottom contact (BC) transistor devices.

The gate, source and drain electrodes and the insulating and semiconducting layer in the FET device may be arranged in any sequence, provided that the source and drain electrode are separated from the gate electrode by the insulating layer, the gate electrode and the semiconductor layer both contact the insulating layer, and the source electrode and the drain electrode both contact the semiconducting layer.

In a more general manner the process of preparing an electronic device, preferably an translucent electronic device, are the following:
a) applying working electrodes, preferably source and drain electrodes onto a substrate or onto a dielectric layer,
b) depositing a layer of preferably semiconducting nanoparticles, dispersed in a liquid carrier, onto the substrate or dielectric layer and the source and drain electrodes, rolling a cylindrical roller over the substrate while the substrate is wetted by the said liquid carrier,
c) optionally removing the fluid from the nanoparticle layer,
d) optionally providing one or more further functional layers onto the nanoparticle layer.

The other components of the device and suitable materials and methods of their preparation are known to the skilled person and described in the literature, for example in U.S. Pat. No. 7,029,945.

For example, various substrates may be used for the fabrication of OE devices, like glass or plastics. Plastic materials are generally preferred, examples including alkyd resins, allyl esters, benzocyclobutenes, butadiene-styrene, cellulose, cellulose acetate, epoxide, epoxy polymers, ethylene-chlorotrifluoro ethylene, ethylene-tetra-fluoroethylene, fibre glass enhanced plastic, fluorocarbon polymers, hexafluoropropylenevinylidene-fluoride copolymer, high density polyethylene, parylene, polyamide, polyimide, polyaramid, polydimethylsiloxane, polyethersulphone, poly-ethylene, polyethylenenaphthalate, polyethyleneterephthalate, polyketone, polymethylmethacrylate, polypropylene, polystyrene, polysulphone, polytetrafluoroethylene, polyurethanes, polyvinylchloride, silicone rubbers, silicones. Preferred substrate materials are polyethyleneterephthalate, polyimide, and polyethylenenaphthalate. The substrate may also comprise any plastic material, metal or glass that is coated with the above materials. The substrate should preferably be homogenous to ensure good pattern definition. The substrate may also be uniformly pre-aligned by extruding, stretching, rubbing or by photochemical techniques to induce the orientation of the elongated nanoparticles in order to enhance carrier mobility.

The source, drain and gate electrodes can be deposited by liquid coating, such as spray-, dip-, web- or spin-coating, by vacuum deposition or vapor deposition methods or by a process according to the invention using conducting nanoparticles. Suitable electrode materials and deposition methods are known to the person skilled in the art. Suitable electrode materials include, without limitation, inorganic or organic materials, or composites of the two. Examples for suitable conductor or electrode materials include polyaniline, polypyrrole, PEDOT or doped conjugated polymers, further dispersions or pastes of graphite, carbon nanotubes or graphene flakes or particles of metal, such as Au, Ag, Cu, Al, Ni or their mixtures as well as sputtercoated or evaporated metals, like e.g. Cu, Cr, Pt/Pd etc., and semiconductors like e.g. ITO. Organometallic precursors may also be used deposited from a liquid phase.

A PV device according to the present invention preferably comprises:
a low work function electrode (for example Aluminum),
a high work function electrode (for example ITO), one of which is transparent,
a single blend layer or bilayer of consisting of a hole transporting and an electron transporting material and their mixtures; the bilayer can exist as two distinct layers, or a blended mixture (see for example Coakley, K. M. and McGehee, M. D. Chem. Mater. (2004), 16, 4533),
an optional conducting polymer layer (such as for example PEDOT:PSS) to modify the work function of the high work function electrode to provide an ohmic contact for the hole,
an optional coating on the high workfunction electrode (such as LiF) to provide an ohmic contact for electrons,

wherein the hole and/or electron transporting material comprises roll casted nanoparticles according to the present invention.

Alternatively, the deposited nanoparticles according to the present invention can be used in organic light emitting devices or diodes (LEDs), e.g., in display applications or as backlight of e.g. liquid crystal displays. Commonly LEDs are realized using multilayer structures. An emission layer is generally sandwiched between one or more electron-transport and/or hole-transport layers. By applying an electric voltage electrons and holes as charge carriers move towards the emission layer where their recombination leads to the excitation and hence luminescence of the luminophor units contained in the emission layer. The nanoparticles can be employed in one or more of the charge transport layers and/or in the emission layer of the LED device, corresponding to their electrical and/or optical properties. For example, electroluminescent nanowires may be used as the emissive layer in LED devices as described in U.S. Pat. No. 6,918,946 or U.S. Pat. No. 6,846,565.

Nanoparticles comprising a conducting material can also be used as substitute for solid metal in applications including, but not limited to, charge injection layers and ITO planarising layers in LED applications, films for flat panel displays and touch screens, antistatic films, printed conducting substrates, patterns or tracts in electronic applications such as printed circuit boards and condensers.

Throughout the description and claims of this specification, the words “comprise” and “contain” and variations of the words, for example “comprising” and “comprises”, mean “including but not limited to”, and are not intended to (and do not) exclude other components. Unless the context clearly indicates otherwise, as used herein plural forms of the terms herein are to be construed as including the singular form and vice versa.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification and in the claims may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

Further combinations of the embodiments of the current invention and variants of the invention are also disclosed by the claims.

The invention will now be described in more detail by reference to the following examples, which are illustrative only and do not limit the scope of the invention.

Abbreviations

NW/NWs nanowire/nanowires

Au/Ge/Si/Al Gold/Germanium/Silicon/Aluminium

(BG) FET (bottom gate) field effect transistor

OE organic electronics

PV photovoltaic

### BRIEF DESCRIPTION OF THE DRAWINGS

FIG. 1. shows the transfer curves of NW transistors deposited by using the roll cast method.

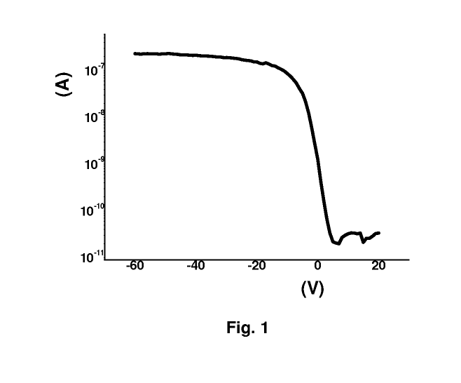

### EXPERIMENTAL

The nanowires used in the examples of this application were produced by solid-liquid-solid (SLS) growth as exemplified by A. T. Heitsch et al. in J. Am. Chem. Soc. (2008) 130, 5436-7. The examples of the invention are however not limited to nanowires produced by the SLS approach, as described above and in any of the publications Adv. Mater. (2004) 7, 646-649, J. Am. Chem. Soc. (2002) 124(7), 1424-1429, and Chem. Mater. (2005) 17, 5705-5711. Also vapour-based growth methods of nanowires are applicable.

The nanoparticles used are germanium nanowires passivated with isoprene. The passivation molecules help the nanowires easily being suspended in organic solvents, which can also act as a protection layer to avoid oxidation of the germanium.

The nanowires were dispersed in organic solvents like dichlorobenzene, wherein the nanowires disperse very well. The concentration of the nanowires was 0.5 mg/ml solvent. Ultrasonication was used to evenly disperse the nanowires in the solvent before application.

The substrates used for nanowires transistors characterization are gate substrates on silicon wafer, where the doped silicon was used as a global gate electrode, with 230 nm SiO₂ as dielectric layer on top. The patterned Au source and drain electrodes are deposited on top of the dielectric layer, ITO is used as adhesion layer of Au. The source and drain channel is 20 μm with fingers architecture.

Before nanowire deposition, the substrates are cleaned using acetone to remove the photoresist. Acetone and isopropanol are used for further cleaning, in the end a 10 min ozone cleaning process is used. The last step helps to remove the organic compound residual on the surface and also makes the surface hydrophilic by creating OH bonds.

The transfer curves of the transistors are measured by using an Agilent™ 4155C semiconductor parameter analyzer controlled from a personal computer.

The method used for nanowires deposition here will be named “roll cast method”. To show the advantages of such method, a conventional drop cast method is also demonstrated.

### 1) COMPARATIVE EXAMPLE

### Drop Cast Method

The drop cast method is a simple method to deposit nanowires. One uses a pipette to take a small amount of nanowires solution, and drops it on the cleaned substrates. During the drying process of the solvent, the nanowires aggregated, the “coffee stain” effect was clearly observed on the edges of the original drop.

### 2) EXAMPLE

### Preparation of a Roller

A light weight glass roller is made from a glass pipette or glass tube. The surface of the roller is cleaned by using Decon 90 in ultrasonic bath and washed with water, dried by using N₂ gas, then coated with amorphous perfluoropolymer (CYTOP™, AGC, Japan) on its surface, which makes its surface soft and also hydrophobic. The coating was made by dropping some polymer solution on the tube while rotating and applying a plastic blade for achieving a uniform surface. The tube was dried at 100° C. for one hour.

### 3) EXAMPLE

### Roll Casting

The cleaned substrates are put on a glass slide and tiled with a small degree (30°) by adding a small object under one side of the slide. Some nanowires solution is dropped on the glass until it covers all the surface.

The roller is put on the glass slide (upper side) and rolled naturally over the substrate under gravity force. The roller squeezes the nanowires solution into a very thin layer as it rolls over the substrate The nanowires are adhered onto the substrate, and the drying of the very thin remaining solvent does not cause any aggregation anymore. The distribution of the nanowires on the surface is checked by a TEM image. The nanowires are spread out randomly with hardly any clumps.

### 4) EXAMPLE

### Comparison of Transistor Function

The nanowires are deposited on substrates by using the drop cast and the roll cast method. The nanowires cover the substrate where it comprises a SiO₂ dielectric layer and patterned source and drain electrodes on the dielectric layer. After the nanowire-deposition, the substrates are transferred into a nitrogen filled glove box. There the transistor's properties are measured. The on/off ratio is 6·10⁴ for the device prepared by the inventive roll cast method.

The device prepared by drop casting comprises stains consisting of clumped nanowires. It has an on/off ratio of about 10.

The comparison shows that the roll casting process according to the invention provides a more uniform distribution of the nanoparticles on the surface compared to the conventional dropping method. Additionally the performance of a transistor device made by the inventive method is clearly advantageous over the conventional approach.

1. Process for deposition of elongated nanoparticles onto a substrate, comprising the steps:
1) wetting the substrate with a liquid carrier comprising elongated nanoparticles, and
2) rolling of a cylindrical roller over the substrate while the substrate is wetted by the said liquid carrier.

2. Process according to claim 1, characterized in that the nanoparticles are selected from the group consisting of nanowires, nanorods, nanotubes, nanodiscs, nanoribbons and/or combinations thereof.

3. Process according to claim 1, characterized in that the nanoparticles are dispersed or dissolved in an organic solvent.

4. Process according to claim 1, characterized in that the nanoparticles comprise one or more semiconducting materials, transition metals, or alloys or mixtures of the aforementioned.

5. Process according to claim 1, characterized in that the nanoparticles comprise a passivation layer.

6. Process according to claim 1, characterized in that it comprises a third step, whereby the deposited nanoparticles are dried, any residual liquid carrier is removed and/or any monomers comprised in the liquid carrier are polymerized.

7. Process according to claim 1, characterized in that the surface of the cylindrical roller comprises a polymer.

8. Process according to claim 1, characterized in that after the deposition the nanoparticles are randomly dispersed on the substrate.

9. A charge transport or conducting or semiconducting component in an electronic, electro-optical, photo-voltaic, electroluminescent or optical device or in a sensor, wherein said component contains nanoparticles deposited by a process according to claim 1.

10. Process for preparing an electronic, electro-optical, photo-voltaic, electroluminescent or optical device, comprising the following steps:
a) applying working electrodes onto a substrate or onto a dielectric layer,
b) depositing a layer of nanoparticles onto the substrate or dielectric layer and the working electrodes by a process according to claim 1,
c) drying the layer of nanoparticles, and
d) optionally providing one or more further functional layers onto the nanoparticle layer.

11. Method for assaying the electronic or optical characteristics of elongated nanoparticles comprising the steps:
deposition of the elongated nanoparticles onto a substrate by a process according to claim 1, measuring at least one electronic or optical characteristic value of the deposited layer.

12. Method according to claim 11, wherein the substrate comprises electrodes, transistor elements and/or the substrate is transparent.

13. Electronic, electro-optical, photo-voltaic, electroluminescent or optical device, comprising conducting or semiconducting nanoparticles and working electrodes, characterized in that the nanoparticles are deposited according to claim 1.

14. Device according to claim 13, characterized in that it is a field effect transistor comprising
a substrate,
a gate electrode,
a dielectric layer,
source and drain electrodes, and
a semiconducting layer comprising said nanoparticles.
